(19) United States
(12) Patent Application Publication
(10) Pub. No.: US 2026/0159700 A1
(43) Pub. Date: Jun. 11, 2026

(54) CURABLE COMPOSITION AND INSULATING FILM

(71) Applicant: DUPONT ELECTRONICS, INC., WILMINGTON, DE (US)

(72) Inventors: CHU-YI LEE, HSINCHU (TW); YU-TE LIAO, HSINCHU (TW); YU-CHENG CHEN, HSINCHU (TW)

(21) Appl. No.: 19/408,989

(22) Filed: Dec. 4, 2025

Related U.S. Application Data
(60) Provisional application No. 63/730,240, filed on Dec. 10, 2024.

(51) Int. Cl. C09D 4/06; C09D 7/20; C09D 7/40; C09D 7/61; C09D 123/08; C09D 125/16; C09D 135/00; C09D 171/00; H05K 1/03; H05K 3/02

(52) U.S. Cl. CPC C09D 4/06; C09D 7/20; C09D 7/61; C09D 7/69; C09D 123/0838; C09D 125/16; C09D 135/00; C09D 171/00; H05K 1/032; H05K 3/027

(57) ABSTRACT

The present disclosure provides a curable composition comprising: (A) copolymer with at least one reactive group; (B) crosslinker; (C) polymerization initiator; and (D) boron nitride. The present disclosure also provides an insulating film comprising the aforementioned curable composition, which are particularly suited for manufacturing printed circuit boards (PCBs). The insulating film exhibit excellent electrical properties, including low dissipation factor (Df) and a low coefficient of thermal expansion (CTE). Furthermore, the insulating film provides significant advantages in reducing the production time in PCB manufacturing processes that involve a plasma etching step.

### FIELD OF THE DISCLOSURE

The disclosure relates in general to a curable composition containing boron nitride, and more particularly to an insulating film and/or a print circuit board comprising the same.

### BACKGROUND OF THE DISCLOSURE

Due to the current trend towards thinner and lighter electronic products, print circuit boards (PCBs) must have higher wiring density. PCB is generally composed of multiple insulating and conductive layers stacked on top of each other. To achieve high wiring density, through holes or blind holes are provided to connect circuit between different conductive layers.

The conventional via fabricating technology uses laser light as a drilling tool. The friction generated by drilling creates a resin smear on the channel walls. This smear must be removed to enable an optimal connection. Generally, a wet process is employed after laser drilling to remove smear and form suitable through holes. This wet process includes surface cleaning, swelling the smear, permanganate de-smear, and neutralization reaction. However, the waste liquid and waste water discharged in each step carry away a large amount of harmful substances, and may worsen the environment and impose damages to human's physical and mental health.

Compared to the subtractive or (modified) semi-additive process in PCB manufacturing, forming pattern and/or via by plasma etching is considered a more environmentally friendly process since it does not involve a wet process. However, the etching rate of plasma etching is typically too slow to be cost-effective for manufacturing PCB.

In view of the above, there exists a need to develop new materials for PCB insulting layers and the ability to be treated with a plasma etching process brings overall benefits to the printed circuit board industry.

### SUMMARY

To solve the aforementioned problems, the present disclosure provides a novel resin composition for an insulating layer of PCB. PCB composed with this material has higher plasma etching rate without sacrificing its electrical and mechanical properties, such as dissipation factor (Df) and the coefficient of thermal expansion (CTE). The novel resin composition is a viable alternative to conventional PCB insulating layer.

According to one aspect of the present disclosure, a curable composition is provided. The curable composition comprises:
100 parts by weight of a copolymer (A) with at least one reactive group;
250-350 parts by weight of a crosslinker (B);
0.5-6 parts by weight of a polymerization initiator (C);
50-900 parts by weight of boron nitride (D) having a median particle size of 10 μm or less.

According to the second aspect of the present disclosure, an insulating film comprising the aforementioned curable composition is also provided. The insulating film comprises sequentially a support film, a resin layer composed of the above curable composition, and a protective film. The resin layer has a thickness of 10 μm to 60 μm.

According to the third aspect of the present disclosure, a printed circuit board is also provided. The PCB comprises an insulating layer that is a cured product of the above curable composition or is made from the above insulating film.

### BRIEF DESCRIPTION OF THE DRAWINGS

FIG. 1 shows a section view of the testing coupon according to one embodiment of the present disclosure.

### DETAILED DESCRIPTION

Before addressing details of embodiments described below, some terms are defined or clarified.

### Definitions

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this disclosure belongs. In case of conflict, the present specification, including definitions, prevails.

Unless stated otherwise, all percentages, parts, ratios, etc., are by weight.

As used herein, the term “produced from” is synonymous to “comprising”. As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would restrict the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps features, components, or elements do not materially affect the basic and novel characteristic(s) of the claimed disclosure.

The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. For example, when a range of “1 to 5” is recited, the recited range should be construed as including ranges “1 to 4”, “1 to 3”, “1-2”, “1-2 & 4-5”, “1-3 & 5”, and the like. Where a range of numerical values is recited herein, unless otherwise stated, the range is intended to include the endpoints thereof, and all integers and fractions within the range.

Further, unless expressly stated to the contrary, “or” refers to an inclusive “or” and not to an exclusive “or”. For example, a condition A “or” B is satisfied by any one of the following: A is true (or present) and B is false (or not present), A is false (or not present) and B is true (or present), and both A and B are true (or present).

The disclosure is described in detail herein under.

The present disclosure relates to a curable composition comprises:
100 parts by weight of a copolymer (A) with at least one reactive group;
250-350 parts by weight of a crosslinker (B);
0.5-6 parts by weight of a polymerization initiator (C);
50-900 parts by weight of boron nitride (D) having a median particle size of 10 μm or less.

In one embodiment of the present disclosure, the copolymer (A) is derived from a composition comprising a C2-8 olefin (a-1), a C6-20 aromatic vinyl compound (a-2), and a C10-20 aromatic polyene (a-3). The copolymer (A) may be derived from a composition consisting essentially of a C2-8 olefin (a-1), a C6-20 aromatic vinyl compound (a-2), and a C10-20 aromatic polyene (a-3). Alternatively, the copolymer (A) may be derived from a composition consisting of a C2-8 olefin (a-1), a C6-20 aromatic vinyl compound (a-2), and a C10-20 aromatic polyene (a-3).

More particularly, the copolymer (A) may be derived from a composition comprising, consisting essentially of, or consisting of 10-70 wt % of the C2-8 olefin (a-1), 10-60 wt % of the C6-20 aromatic vinyl compound (a-2), and 1-30 wt % of the C10-20 aromatic polyene (a-3) based on the total weight of the copolymer is 100 wt %.

In the present disclosure, an olefin refers to an unsaturated hydrocarbon having at least one double bond. In one embodiment of the present disclosure, the C2-8 olefin (a-1) may be ethylene, propylene, 1-butylene, 2-butylene, isobutylene, 1-pentene, 2-pentene, 2-methyl-1-butene, 3-methyl-1-butene, 2-methyl-2-butene, 1-hexene, 2-hexene, 3-hexene, butadiene, isoprene, or a combination thereof.

In the present disclosure, an aromatic vinyl compound refers to an aromatic compound having one vinyl group. In one embodiment of the present disclosure, the C6-20 aromatic vinyl compound (a-2) may be styrene, methylstyrene, methoxystyrene, monochlorostyrene, dichlorostyrene, trichlorostyrene, monobromostyrene, dibromostyrene, tribromostyrene, iodostyrene, diiodostyrene, triiodostyrene, vinylphenol, 2-methoxy-4-vinylphenol, vinylnaphthalene, vinylanthracene, N-vinylcarbazole, vinylfuran, vinylpyridine, or a combination thereof.

In the present disclosure, an aromatic polyene refers to an aromatic compound having at least two alkene groups. In one embodiment of the present disclosure, the C10-20 aromatic polyene (a-3) may be divinylbenzene, divinylnaphthalene, divinylanthracene, propenylstyrene, butenylstyrene, 1,2-bis(vinylphenyl) ethane, or a combination thereof.

In one embodiment of the present disclosure, the copolymer (A) may be a copolymer of ethylene, styrene and divinylbenzene.

In one embodiment of the present disclosure, the copolymer (A) has a number average molecular weight (Mn) of 15,000 to 100,000, particularly 20,000 to 100,000, more particularly 30,000 to 100,000, and even more particularly 35,000 to 80,000. In addition, the copolymer (A) may have a number of the reactive group per Mn of 1 to 10.

The crosslinker (B) is capable of inducing crosslinking reaction of the copolymer (A). In one embodiment of the present disclosure, the crosslinker (B) has at least one functional group selected from the group consisting of a maleimide group, an aromatic vinyl group, an aliphatic vinyl group, a cycloaliphatic vinyl group, an acrylate group, a (meth)acrylate group, and combinations thereof. The term “(meth)acrylate” includes both acrylate and methacrylate.

In one specific embodiment of the present disclosure, the functional group is a maleimide group, and the crosslinker (B) comprises 4,4′-diphenylmethane bismaleimide, m-phenylene bismaleimide, 2,2′-bis[4-(4-maleimidophenoxy)phenyl]propane, 3,3′-diethyl-5,5′-dimethyl-4,4′-diphenylmethane bismaleimide, 4-methyl-1,3-phenylene bismaleimide, 1,6′-bismaleimide-(2,2,4-trimethyl)hexane, or a combination thereof.

In another specific embodiment of the present disclosure, the crosslinker (B) is divinylbenzene and the functional group is an aromatic vinyl group.

In another specific embodiment of the present disclosure, the crosslinker (B) is a polyether and the functional group is an aromatic vinyl group.

In another specific embodiment of the present disclosure, the crosslinker (B) is an oligo(phenylene ether) and the functional group is an aromatic vinyl group. The oligo(phenylene ether) may be terminated with a (meth)acrylate group, an acrylate group, a vinylbenzyl group, a vinyl benzoate group, or a combination thereof.

In another specific embodiment of the present disclosure, the crosslinker (B) is oligo(phenylene ether) terminated with a (meth)acrylate group and the functional group is a (meth)acrylate group.

The polymerization initiator (C) is capable of initiating the polymerization of the copolymer (A) and/or the crosslinker (B). Non-limiting examples of the polymerization initiator (C) include 2,5-dimethyl-2,5-bis(t-butylperoxy)hexane, 2,3-dimethyl-2,3-diphenylbutane, 1-bis(t-butylperoxy)-3, 3, 5-trimethylcyclohexane, benzoyl peroxide, lauroyl peroxide, di-t-butyl peroxide, di-(2-t-butylperoxyisopropyl)benzene, dicumyl peroxide, t-butyl peroxybenzoate, t-butyl peroxypivalate, methyl ethyl ketone peroxide, cyclohexanone peroxide, diisopropyl peroxydicarbonate, dicyclohexyl peroxycarbonate, and combinations thereof.

The curable composition of the present disclosure utilizes boron nitride (D) as a filler. The boron nitride initiator has a median particle size of 10 μm or less. It is surprisingly found that the boron nitride (D) may be critical for achieving higher plasma etching rate, especially compared to silica. Therefore, in one embodiment of the present disclosure, the curable composition is free of silica.

The amount of the boron nitride (D) can be 50-900 parts by weight, particularly 150-850 parts by weight, more particularly 250-800 parts by weight, based on 100 parts by weight of the copolymer (A).

In one embodiment of the present disclosure, the curable composition further comprises an additive (E). Non-limiting examples of the additive include an adhesion promoter, an antioxidant, a colorant, a defoamer, a flame retardant, a polymerization inhibitor, a thickener, a solvent, and combinations thereof.

In one embodiment of the present disclosure, the additive (E) is a flame retardant selected from the group consisting of a brominated flame retardant, a phosphorus flame retardant, a nitrogen flame retardant, and combinations thereof.

In one specific embodiment of the present disclosure, the additive (E) is a brominated flame retardant. Non-limiting examples of the brominated flame retardant include decabromodiphenyl ether, decabromodiphenyl ethane, brominated styrene and tetrabromophthalic acid amide.

In another specific embodiment of the present disclosure, the additive (E) is a phosphorus flame retardant. Non-limiting examples of the phosphorus flame retardant include an inorganic phosphorus, a phosphate compound, a phosphoric acid compound, a hypophosphorous acid compound, a phosphorus oxide compound, phosphazene and modified phosphazene. More specifically, the phosphorus flame retardant may be 9,10-dihydro-9-oxa-10-phosphaphenanthrene-10-oxide (DOPO), 10-(2,5-dihydroxyphenyl)-9,10-dihydro-9-oxa-10-phosphaphenanthrene-10-oxide (DOPO-HQ), or tris(2,6-dimethylphenyl) phosphorus.

In another specific embodiment of the present disclosure, the additive (E) is a nitrogen flame retardant. Non-limiting examples of the nitrogen flame retardant include a triazine compound, a cyanuric acid compound, an isocyanic acid compound and phenothiazine.

In one embodiment of the present disclosure, the additive (E) is a solvent comprising cyclohexanone, cyclopentanone, isophorone, methyl ethyl ketone, methyl isobutyl ketone, toluene, xylene, naphtha solvent of boiling point between 100° C. to 200° C., or combinations thereof.

The second aspect of the present disclosure is related to an insulating film for fabricating a printed circuit board. The insulating film comprising sequentially:
a support film;
a resin layer composed of the above curable composition; and
a protective film.

In one embodiment of the present disclosure, the resin layer has a thickness of 10 μm to 60 μm. In one embodiment of the present disclosure, the support film is a thermoplastic film having a thickness of 10 μm to 50 μm, or a metallic foil having a thickness of 1 μm to 25 μm. In one embodiment of the present disclosure, the protective film is a thermoplastic film has a thickness of 10 μm to 50 μm.

In one embodiment of the present disclosure, the support film and the protective film are each independently composed of a polymeric material selected from the group consisting of polyethylene, polypropylene, polyvinyl chloride, polyethylene terephthalate, polyethylene naphthalate, polycarbonate, and polyimide.

In one embodiment of the present disclosure, the support film is a metallic foil selected from the group consisting of Au, Ag, Cu, Al, and alloys thereof.

In one embodiment of the present disclosure, the resin layer is cured at 100° C. to 250° C. for 60 minutes to 240 minutes.

In one embodiment of the present disclosure, the resin layer after curing has a dissipation factor (Df) of 0.003 or less when measured at 10 GHz and 23° C.

In one embodiment of the present disclosure, the resin layer after curing has a coefficient of thermal expansion (CTE) of 70 ppm/K or less between 30° C. to 120° C.

In one embodiment of the present disclosure, the resin layer after curing has a plasma etching rate of 0.4 μm/min or more, particularly 0.4-7.5 μm/min. The plasm etching is performed under a chamber pressure of 2 Pa (15 mtorr) by applying a radiofrequency (RF) power of 13.56 MHz, an ignition power of 8000 Watts, a DC bias of 5000 Watts setting with a gas mixture of oxygen, tetrafluoromethane (carbon tetrafluoride, CF4) and nitrogen at a ratio of 2:2:1, and a flow rate of 1250 mL/sec for 30 minutes.

The third aspect of the present disclosure is related to a printed circuit board comprising an insulating layer that is a cured product of the above curable composition or is made from the above insulating film.

In one embodiment of the present disclosure, the circuit is fabricated by a method comprising a plasma etching step for via and/or trench formation.

In one embodiment of the present disclosure, the method for forming the circuit is a semi-additive process (SAP) or a modified semi-additive process (mSAP).

### Composition and Film Preparation

The curable composition of the present disclosure comprises the following components: (A) a copolymer with at least one reactive group, (B) a crosslinker, (C) a polymerization initiator, (D) boron nitride, and, optionally, (E) an additive. In one non-limiting aspect, the composition aspect of the present disclosure may be prepared from the components listed in Table A below. Components (A) to (C) and (E) were mixed until fully dissolved to form a base. Then component (D) was added to the base, followed by using a rotary mixer to disperse uniformly. The composition was prepared into two different samples: resin coated copper (RCC) film structure and resin sheet structure for more test.

TABLE A

| Component | Model name | Manufacturer | Description |
|---|---|---|---|
| (A) copolymer | LDM-02C | Denka | Copolymer of ethylene, styrene and divinylbenzene, |
| | | | 50% in toluene, Mn ~2 × 10⁴ |
| (A′) polymer | FG1901GT | Kraton | Polystyrene-block-poly(ethylene-ran-butylene)- |
| | | | block-polystyrene, CAS NO. 66070-58-4 |
| (A′) polymer | Ricon 154 | Cray Valley | Butadiene rubber, CAS No. 9003-17-2 |
| (B) crosslinker | MIR3000 | Nippon kayaku | Biphenyl backbone multifunctional maleimide, 70% |
| | | | in mixed solvent, |
| | | | Maleimide equivalent = 400~460 g/eq. |
| (B) crosslinker | BMI70 | Daiwakasei | Bismaleimide, CAS No. 105391-33-1 |
| (B) crosslinker | Elpac HC-G0024 | JSR | Styryl end group poly ether resin, 61% in toluene |
| | | | solution |
| (B) crosslinker | OPE2st-1200 | Mitsubishi Gas | Styryl end group polyphenyl ether, 67% in toluene |
| | | Chemical | solution, CAS No. 558452-77-0 |
| (B) crosslinker | DVB | Nova-Matls | Divinylbenzene, CAS No. 1321-74-0 |
| (C) polymerization | DCP | Sigma aldrich | Dicumyl peroxide, CAS No. 80-43-3 |
| initiator | | | |
| (D) boron nitride | PT132 | Momentive | Boron nitride, having a median particle size D50 of 5 |
| | | | μm |
| (D′) filler | SO-1500 | Sibelco | Fused silica, having a median particle size D50 of 5 |
| | | | μm |
| (E) additive | KBM403 | Shin-Etsu | Adhesion promotor, 3-glycidoxypropyl |
| | | | trimethoxysilane, CAS No. 2530-83-8 |
| (E) additive | DISPERBYK- | BYK | Surfactant, polyglycol polyester modified |
| | 2155 | | polyalkylene imine |
| Support film | MT18FL | Mitsui | Copper foil |
| Protective film | 38X | Lintec | Release agent-coated PET film |
| Protective film | MA411 | Oji Film | OPP release film |

The preparation procedure of Examples, Comparative Examples and Reference Examples are described below, wherein the relevant weight for each component is presented excluding the weight of solvent.

### Example E1

12 g of LDM-02C (copolymer (A)), 12 g of MIR3000 (crosslinker (B)), 12 g of BMI70 (crosslinker (B)), 8 g of Elpac HC-G0024 (crosslinker (B)), 4 g of DVB (crosslinker (B)), 0.4 g of DCP (polymerization initiator (C)), 2 g of KBM403 (additive (E)) and 0.34 g of DISPERBYK-2155 (additive (E)) were mixed and stirred until fully dissolved. Subsequently, 34 g of PT132 (boron nitride (D)) was added, and the mixture was dispersed uniformly using a high-speed rotary mixer to prepare a resin varnish.

The resulting resin varnish was coated onto a supporting film MT18FL-3 μm (two-layered copper foil with an upper layer having a thickness of 3 μm and a lower layer having a thickness of 18 μm) using suitable quadruple film applicators (purchased from GMA Machinery, Taiwan) on an automatic coater (model Coatmaster 510, purchased from Erichsen GmbH) at a coating speed of approximately 60 mm/s. The coated film was then dried at 100° C. for 3 minutes in a circulation oven (model DCM704, purchased from Channel Instruments, Taiwan). After drying, the film was covered with 38X (protective film), forming a Resin Coated Copper (RCC) film structure sample.

Additionally, the resin varnish was coated onto 38X (protective film) and dried at 100° C. for 3 minutes. The dried film was then covered with MA411 (protective film), forming a resin sheet structure.

Thickness of the resin composition layer was 30 μm in the two structures above.

### Example E2

The preparation procedure of Example E1 was followed, except that the amount of PT132 (boron nitride (D)) was adjusted to 50 g and the amount of DISPERBYK-2155 (additive (E)) was adjusted to 0.5 g.

### Example E3

The preparation procedure of Example E1 was followed, except that the amount of PT132 (boron nitride (D)) was adjusted to 93 g and the amount of DISPERBYK-2155 (additive (E)) was adjusted to 0.93 g.

### Example E4

The preparation procedure of Example E2 was followed, except that the amount of Elpac HC-G0024 (crosslinker (B)) was adjusted to 12 g and DVB (crosslinker (B)) was not used.

### Example E5

The preparation procedure of Example E2 was followed, except that the amount of DVB (crosslinker (B)) was adjusted to 12 g and Elpac HC-G0024 (crosslinker (B)) was not used.

### Example E6

The preparation procedure of Example E2 was followed, except that Elpac HC-G0024 (crosslinker (B)) was replaced by 8 g of OPE2st-1200 (crosslinker (B)).

### Comparative Example CE1

The preparation procedure of Example E1 was followed, except that PT132 (boron nitride (D)) was replaced by SO-1500 (filler (D′)).

### Comparative Example CE2

The preparation procedure of Example E2 was followed, except that PT132 (boron nitride (D)) was replaced by SO-1500 (filler (D′)).

### Comparative Example CE3

The preparation procedure of Example E3 was followed, except that PT132 (boron nitride (D)) was replaced by SO-1500 (filler (D′)).

### Reference Example RE1

The preparation procedure of Example E2 was followed, except that LDM-02C (copolymer (A)) was replaced by FG1901GT (polymer (A′)).

### Reference Example RE1

The preparation procedure of Example E2 was followed, except that LDM-02C (copolymer (A)) was replaced by Ricon 154 (polymer (A′)).

The components of above Examples, Comparative Examples and Reference Examples are listed in Table B. The materials are listed by their dried mass in the table B. The Examples, Comparative Examples and Reference Examples were prepared in a similar manner. The difference between Examples and Comparative Examples lies in the filler used, wherein the Examples use boron nitride while the Comparative Examples use silica. The difference between Examples and Reference Examples lies in the type of copolymer/polymer.

TABLE B

| Component | | | | | | | | | | | | |
|---|---|---|---|---|---|---|---|---|---|---|---|---|
| (unit: g) | Model name | E1 | E2 | E3 | E4 | E5 | E6 | CE1 | CE2 | CE3 | RE1 | RE2 |
| (A) copolymer | LDM-02C | 12 | 12 | 12 | 12 | 12 | 12 | 12 | 12 | 12 | | |
| (A′) polymer | FG1901GT | | | | | | | | | | 12 | |
| | Ricon 154 | | | | | | | | | | | 12 |
| (B) crosslinker | MIR3000 | 12 | 12 | 12 | 12 | 12 | 12 | 12 | 12 | 12 | 12 | 12 |
| | BMI70 | 12 | 12 | 12 | 12 | 12 | 12 | 12 | 12 | 12 | 12 | 12 |
| | Elpac | 8 | 8 | 8 | 12 | | | 8 | 8 | 8 | 8 | 8 |
| | HC-G0024 | | | | | | | | | | | |
| | OPE2st-1200 | | | | | | 8 | | | | | |
| | DVB | 4 | 4 | 4 | | 12 | 4 | 4 | 4 | 4 | 4 | 4 |
| (C) polymerization | DCP | 0.4 | 0.4 | 0.4 | 0.4 | 0.4 | 0.4 | 0.4 | 0.4 | 0.4 | 0.4 | 0.4 |
| initiator | | | | | | | | | | | | |
| (D) boron nitride | PT132 | 34 | 50 | 93 | 50 | 50 | 50 | | | | 50 | 50 |
| (D′) filler | SO-1500 | | | | | | | 34 | 50 | 93 | | |
| (E) additive | KBM403 | 2 | 2 | 2 | 2 | 2 | 2 | 2 | 2 | 2 | 2 | 2 |
| | DISPERBYK- | 0.34 | 0.5 | 0.93 | 0.5 | 0.5 | 0.5 | 0.34 | 0.5 | 0.93 | 0.5 | 0.5 |
| | 2155 | | | | | | | | | | | |

*The median particle size (D50) of boron nitride is measured by a laser scattering particle size distribution analyzer

### Measuring Plasma Etching Rate of the RCC Film

### Test Coupon Preparation

RCC films of above Examples, Comparative Examples and Reference Examples were further processed as follows to prepare a coupon for plasma etching testing:
Lamination: RCC film of size 15 cm×20 cm was laminated on a CZ-8100 (pre-treatment solution made by MEC) pretreated EM526 H/H core board (15 cm×20 cm, 0.6 mm thick) by vacuum laminator. The vacuum laminator was heated to 100° C. and vacuumed for 30 seconds, then pressured to 7 kgf/cm² for 90 seconds at 100° C.
Curing: The laminated sample was cured in an air flow oven with 130° C. for 30 minutes; 180° C. for 30 minutes; and then 200° C. for 90 minutes.
Copper Removal: After curing, the supporting film MT18FL (carrier copper of RCC film) was removed.
Tenting: a hard mask window (Line/Space pattern of 40 μm/40 μm) was formed on the surface of the cured sample (without the carrier). The sample was then cut to a size of 5 cm×5 cm to serve as the testing coupon.

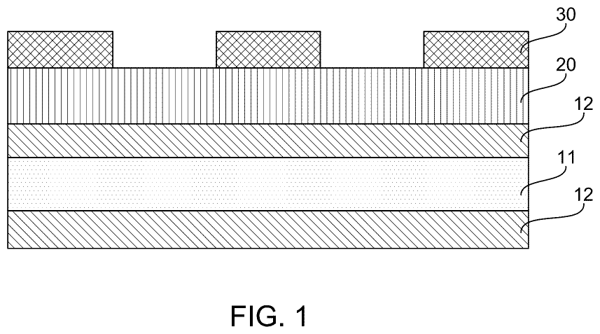

The structure of the testing coupon is shown on FIG. 1. The testing coupon comprises core layer EM526 (11) and its covering copper (12), dielectric layer 20 (curable composition of the present disclosure), and a metal hard mask 30. The following plasma treatment will etch the dielectric layer 20 through the window of the hard mask 30.

### Plasma Etching and Measurement

The coupons of Examples, Comparative Examples and Reference Examples were subjected to plasma treatment, and the etching depth was measured using a 3D Optical Microscope (Olympus Lext OLS5100, 50× objective lens). The etching depth is the depth from the surface subtracts the thickness of hard mask. The etching rate was calculated by dividing the etching depth by the processing time. The test results of each coupon are listed in Table C.

TABLE C

| | E1 | E2 | E3 | E4 | E5 | E6 | CE1 | CE2 | CE3 | RE1 | RE2 |
|---|---|---|---|---|---|---|---|---|---|---|---|
| plasma etching | 0.41 | 0.57 | 0.71 | 0.6 | 0.6 | 0.6 | 0.31 | 0.25 | 0.22 | 0.6 | 0.58 |
| rate (μm/min) | | | | | | | | | | | |

*Plasma Etching Conditions: Ignition 8 kW; Bias 5 kW; RF Frequency 13.56 MHz; Gas flow rates Oxygen 500 cc/min, CF₄ 500 cc/min, N₂ 250 cc/min; Etching duration 30 minutes

As shown in Table C, the plasma etching rates of Examples E1-E6 of the present disclosure are greater than 0.4 μm/min. In contrast, Comparative Examples CE1-CE3 have relatively low plasma etching rates, and may not be suitable for industry use. This shows that boron nitride may be critical for achieving higher plasma etching rate, especially compared to silica.

### Measuring Df and CTE of the Resin Sheet

### Sample Preparation

Resin sheets of Examples, Comparative Examples and Reference Examples were further processed as follows to prepare a sample for measuring Df and CTE:
Lamination: multiple resin sheets of 10 cm×10 cm size were laminated together to form one dielectric layer with thickness of 60 μm by vacuum laminator. The vacuum laminator was heated to 100° C. and vacuumed for 30 seconds, then pressured to 7 kgf/cm² for 90 seconds at 100° C.
Curing: The laminated sample was cured in an air flow oven with 130° C. for 30 minutes; 180° C. for 30 minutes; and then 200° C. for 90 minutes.
PET film Removal: After curing, the protective layer 38X (PET film) was removed.
Dissipation factor (Df) of the dielectric/insulting layer was measured by resonance cavity method at a frequency of 10 GHz. Coefficient of thermal expansion (CTE) was measured by TA Instruments TMA 650 thermomechanical analyzer. The sample was heated to 280° C., cooled down to room temperature, and then reheated at a rate of 5° C./min with a preload force of 0.098 N. The CTE was calculated from the slope of dimension change to temperature from 50° C. to 100° C. by the second cycle of heating. The test results of each sample are listed in Table D.

TABLE D

| | E1 | E2 | E3 | E4 | E5 | E6 | CE1 | CE2 | CE3 | RE1 | RE2 |
|---|---|---|---|---|---|---|---|---|---|---|---|
| Df @10 GHz | 0.0013 | 0.0014 | 0.0014 | 0.0017 | 0.0014 | 0.0016 | 0.0029 | 0.0032 | 0.0036 | 0.0014 | 0.0023 |
| (23° C.) | | | | | | | | | | | |
| CTE | 65 | 59 | 28.5 | 56 | 44.5 | 50 | 68 | 58 | 40 | >75 | >75 |
| (ppm/° C.) | | | | | | | | | | | |

As shown in Table D, the insulating films of Examples E1-E6 with the present curable composition exhibit excellent electrical properties, including low dissipation factor (Df), and low coefficient of thermal expansion (CTE). In contrast, the insulating films of Comparative Examples CE1-CE3 are not desirable because they exhibit higher dissipation factor (Df) in addition to lower plasma etching rate discussed above. As for Reference Examples, although they have comparable plasma etching rate as shown in Table C, this is achieved at an expense of coefficient of thermal expansion (CTE), with a comparably higher value of ≥75. The comparison between Examples and Reference Examples shows that if the copolymer (A) of the present disclosure is not used, a poor coefficient of thermal expansion (CTE) may be presented despite acceptable plasma etching rate.

Furthermore, the insulating film of the present disclosure provides significant advantages in reducing the production time in PCB manufacturing processes that involve a plasma etching step.

The curable composition of the present disclosure is particularly suitable for manufacturing printed circuit boards (PCBs).

Making a PCB with the Curable Composition
Step 1: Preparation of Substrate with Existing Electrical Circuits

A PCB board with existing electrical circuits was prepared using EM526 (a core board with a thickness of 64 μm and a copper thickness of 22 μm, supplied by Elite Electronic Material Co. Ltd.).

### Step 2: Lamination of RCC Coupons on the Substrate

RCC coupons of example 1 were laminated onto the substrate by laminator (Vigor, VLPH-150 ton vacuum laminator). After lamination, the lower layer of the supporting film was removed and the structure from top to bottom consisted of copper, resin, and substrate.

### Step 3: Patterning the Metal to Form a Hard Mask

A photoresist layer was formed by laminating a dry film (Riston® DI61, 15 μm in thickness, manufactured by DuPont Electronics, Inc.) on the copper layer of the substrate from Step 2 using a roll laminator at 100° C., a pressure of 1.4 MPa, and a rolling speed of 1.0 meter/minute.

The photoresist pattern was created using a direct exposure patterning machine (FDi3 from ORC) with a desired pattern. The uncured part of the photoresist layer was stripped and removed by treatment with a 2% Na₂CO₃ solution for 3 minutes, then rinsed with DI water and dried.

The unmasked copper areas were etched away using a sodium persulfate (Na₂S₂O₈) solution (130 g/L) in a conventional horizontal line at 1 m/min speed until completion, followed by rinsing with DI water and drying. The photoresist pattern was then stripped and removed by treatment with a 10% NaOH solution for 90 seconds, followed by rinsing and drying, forming a copper hard mask on the substrate.

### Step 4: Plasma Etching of the Dielectric Layer

The exposed areas of the dielectric layer were removed by plasma etching using a reactive ion etching plasma system (manufactured by Linco Tech). The process gas was a mixture of CF₄ (500 ml/sec), O₂ (500 ml/sec), and N₂ (250 ml/sec), with an ignition power of 8 kW and a DC bias of 5 kW for 30 minutes, to expose a portion of the existing conductor underneath.

### Step 5: Formation of Seed Layer

A seed layer was formed by sputtering copper using a PVD coating machine (manufactured by UVAT Technology Co., model: UHSD-060302T) with fiducial concentrations of copper 4N. The resulting copper layer had a thickness of 0.8 μm.

### Step 6: Addition of Photoresist Pattern Layer

A photoresist layer was formed by laminating a dry film (Riston® DI61, 25 μm in thickness, manufactured by DuPont Electronics, Inc.) on the copper layer using a roll laminator at 100° C., a pressure of 1.4 MPa, and a rolling speed of 1.0 meter/minute.

The photoresist pattern was created using a direct exposure patterning machine (FDi3 from ORC) with a conventional test pattern by the PCB fabricator, including line/space sets at 15 μm/15 μm. The uncured part of the photoresist layer was stripped and removed by treatment with a 2% Na₂CO₃ solution for 3 minutes, rinsed with DI water, and dried.

### Step 7: Filling the Trench and Via by Metal Deposition

Electroplating was applied to fill the trench and via with copper. The coupon was plated to a copper thickness of 22 μm using 23.13 ASF (amplitude per square feet) for 40 minutes with a plating solution (SFP2M from DuPont).

### Step 8: Removal of Photoresist

The photoresist pattern was stripped by treatment with a 10% NaOH solution for 90 seconds.

### Step 9: Removal of Hard Mask Layer

A flash etch to remove the hard mask layer was conducted by:
Dipping the coupon in a 5 vol % sulfuric acid aqueous solution for 20 seconds.
Transferring the coupon to an etchant solution (ST121-M by Chemtronic Technology) for 48 seconds.
Rinsing with DI water to remove residual solution.

After the flash etch process, the new circuit layer with via and conductor line was completed.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A curable composition, comprising:
100 parts by weight of a copolymer (A) with at least one reactive group;
250-350 parts by weight of a crosslinker (B);
0.5-6 parts by weight of a polymerization initiator (C);
50-900 parts by weight of boron nitride (D) having a median particle size of 10 μm or less.

2. The curable composition of claim 1, wherein the copolymer (A) is derived from a composition comprising a C2-8 olefin (a-1), a C6-20 aromatic vinyl compound (a-2), and a C10-20 aromatic polyene (a-3).

3. The curable composition of claim 2, wherein the copolymer (A) is derived from a composition comprising 10-70 wt % of the C2-8 olefin (a-1), 10-60 wt % of the C6-20 aromatic vinyl compound (a-2), and 1-30 wt % of the C10-20 aromatic polyene (a-3) based on the total weight of the copolymer is 100 wt %.

4. The curable composition of claim 1, wherein the copolymer (A) has a number average molecular weight (Mn) of 15,000 to 100,000 and a number of the reactive group per Mn of 1 to 10.

5. The curable composition of claim 1, wherein the crosslinker (B) has at least one functional group selected from the group consisting of a maleimide group, an aromatic vinyl group, an aliphatic vinyl group, a cycloaliphatic vinyl group, an acrylate group, a (meth)acrylate group, and combinations thereof.

6. The curable composition of claim 1, wherein the polymerization initiator (C) is selected from 2,5-dimethyl-2,5-bis(t-butylperoxy)hexane, 2,3-dimethyl-2,3-diphenylbutane, 1-bis(t-butylperoxy)-3, 3, 5-trimethylcyclohexane, benzoyl peroxide, lauroyl peroxide, di-t-butyl peroxide, di-(2-t-butylperoxyisopropyl)benzene, dicumyl peroxide, t-butyl peroxybenzoate, t-butyl peroxypivalate, methyl ethyl ketone peroxide, cyclohexanone peroxide, diisopropyl peroxydicarbonate, dicyclohexyl peroxycarbonate, and combinations thereof.

7. The curable composition of claim 1, wherein the curable composition further comprises an additive (E), and the additive (E) is selected from the group consisting of an adhesion promoter, an antioxidant, a colorant, a defoamer, a flame retardant, a polymerization inhibitor, a thickener, a solvent, and combinations thereof.

8. The curable composition of claim 7, wherein the additive (E) is a solvent comprising cyclohexanone, cyclopentanone, isophorone, methyl ethyl ketone, methyl isobutyl ketone, toluene, xylene, naphtha solvent of boiling point between 100° C. to 200° C., or combinations thereof.

9. An insulating film for fabricating a printed circuit board, comprising sequentially:
a support film,
a resin layer composed of the curable composition of claim 1, and
a protective film,
wherein the resin layer has a thickness of 10 μm to 60 μm.

10. The insulating film of claim 9, wherein the support film and the protective film are each independently composed of a polymeric material selected from the group consisting of polyethylene, polypropylene, polyvinyl chloride, polyethylene terephthalate, polyethylene naphthalate, polycarbonate, and polyimide.

11. The insulating film of claim 9, wherein the support film is a metallic foil selected from the group consisting of Au, Ag, Cu, Al, and alloys thereof.

12. The insulating film of claim 9, wherein the resin layer after curing has a dissipation factor (Df) of 0.003 or less when measured at 10 GHz and 23° C., and the curing is conducted at 100° C. to 250° C. for 60 minutes to 240 minutes.

13. The insulating film of claim 9, wherein the resin layer after curing has a coefficient of thermal expansion (CTE) of 70 ppm/K or less between 30° C. to 120° C., and the curing is conducted at 100° C. to 250° C. for 60 minutes to 240 minutes.

14. The insulating film of claim 9, wherein the resin layer after curing has a plasma etching rate of 0.4 μm/min or more, and the plasma etching is performed under a chamber pressure of 2 Pa (15 mtorr) by applying a radiofrequency (RF) power of 13.56 MHz, an ignition power of 8000 Watts, a DC bias of 5000 Watts with a gas mixture of oxygen, tetrafluoromethane (carbon tetrafluoride, CF₄) and nitrogen at a ratio of 2:2:1, at a flow rate of 1250 mL/sec for 30 minutes, and the curing is conducted at 100° C. to 250° C. for 60 minutes to 240 minutes.

15. A printed circuit board, comprising an insulating layer that is a cured product of the curable composition of claim 1.

16. The printed circuit board of claim 15, wherein the circuit is fabricated by a method comprising a plasma etching step for via and/or trench formation.
